(19) United States
(12) Patent Application Publication
(10) Pub. No.: US 2025/0102634 A1
(43) Pub. Date: Mar. 27, 2025

(54) TECHNOLOGIES FOR DUAL TUNABLE LASERS IN A PHOTONIC INTEGRATED CIRCUIT DIE

(71) Applicant: Intel Corporation, Santa Clara, CA (US)

(72) Inventor: Sergei Sochava, Sunnyvale, CA (US)

(73) Assignee: Intel Corporation, Santa Clara, CA (US)

(21) Appl. No.: 18/474,393

(22) Filed: Sep. 26, 2023

(51) Int. Cl. G01S 7/481; G01S 7/4911; H01S 5/068

(52) U.S. Cl. CPC G01S 7/4815; G01S 7/4911; H01S 5/068

(57) ABSTRACT

Technologies for tunable lasers in a photonic integrated circuit (PIC) die are disclosed. In an illustrative embodiment, a lidar system includes a PIC die with two lasers. The PIC die includes a switch to switch between the output of the first laser and the output of the second laser. Each laser can be tuned to different peaks of a Bragg grating in the cavity of the laser, and each laser can be frequency swept within the peak of the Bragg grating. In operation, one laser is changed to a different peak of the Bragg grating and allowed to stabilize while the other laser is selected for output and frequency swept. In this manner, one laser stabilizes while the other one is used. Such a lidar system can implement frequency-modulated continuous-wave (FMCW) lidar with a stable, compact laser source.

### BACKGROUND

Photonic integrated circuits (PICs) can be used for several applications, such as light detection and ranging or lidar. Some lidar systems use frequency-modulated continuous-wave lasers, in which a narrow-linewidth laser is swept across a range of frequencies. Such lidar systems may require a laser that can shift between wavelengths in under a few hundred nanoseconds without any subsequent drift. Current solutions tend to be bulky, expensive, or offer poor performance.

### BRIEF DESCRIPTION OF THE DRAWINGS

FIG. 1 is a top-down view of one embodiment of a photonic integrated circuit (PIC) die with two tunable lasers.

FIG. 2 is a graph showing frequencies for one of the lasers in FIG. 1.

FIG. 3 is a graph showing frequencies for one of the lasers in FIG. 1.

FIG. 4 is a graph showing combined frequencies for the two lasers in FIG. 1.

FIG. 5 is a top-down view of one embodiment of a PIC die with two tunable lasers.

FIG. 6 is a top-down view of one embodiment of a PIC die with two tunable lasers.

FIG. 7 is a simplified diagram of one embodiment of a lidar system including the PIC die of FIG. 1.

FIG. 8 is a simplified flow diagram of at least one embodiment of a method for operating the LIDAR system of FIG. 7.

FIG. 9 is a top view of a wafer and dies that may be included in a microelectronic assembly, in accordance with any of the embodiments disclosed herein.

FIG. 10 is a cross-sectional side view of an integrated circuit device that may be included in a microelectronic assembly, in accordance with any of the embodiments disclosed herein.

FIGS. 11A-11D are perspective views of example planar, gate-all-around, and stacked gate-all-around transistors.

FIG. 12 is a cross-sectional side view of an integrated circuit device assembly that may include a microelectronic assembly, in accordance with any of the embodiments disclosed herein.

FIG. 13 is a block diagram of an example electrical device that may include a microelectronic assembly, in accordance with any of the embodiments disclosed herein.

### DETAILED DESCRIPTION

In various embodiments disclosed herein, a photonic integrated circuit (PIC) die includes two lasers and a switch to select between the two lasers. Each of the lasers can change the frequency in relatively large increments of, e.g., 200 gigahertz and also sweep the frequency over, e.g., 5 gigahertz. After changing the frequency by a large increment, the lasers take several microseconds to stabilize. In use, the output of one laser is used while the other laser changes frequency and stabilizes. With this approach, a compact laser source capable of fast wavelength switching for frequency-modulated continuous-wave (FMCW) lidar is possible.

As used herein, the phrase “communicatively coupled” refers to the ability of a component to send a signal to or receive a signal from another component. The signal can be any type of signal, such as an input signal, an output signal, or a power signal. A component can send or receive a signal to another component to which it is communicatively coupled via a wired or wireless communication medium (e.g., conductive traces, conductive contacts, air). Examples of components that are communicatively coupled include integrated circuit dies located in the same package that communicate via an embedded bridge in a package substrate and an integrated circuit component attached to a printed circuit board that send signals to or receives signals from other integrated circuit components or electronic devices attached to the printed circuit board.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact, and “coupled” may indicate elements co-operate or interact, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, the central axis of a magnetic plug that is substantially coaxially aligned with a through hole may be misaligned from a central axis of the through hole by several degrees. In another example, a substrate assembly feature, such as a through width, that is described as having substantially a listed dimension can vary within a few percent of the listed dimension.

It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons.

Reference is now made to the drawings, which are not necessarily drawn to scale, wherein similar or same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

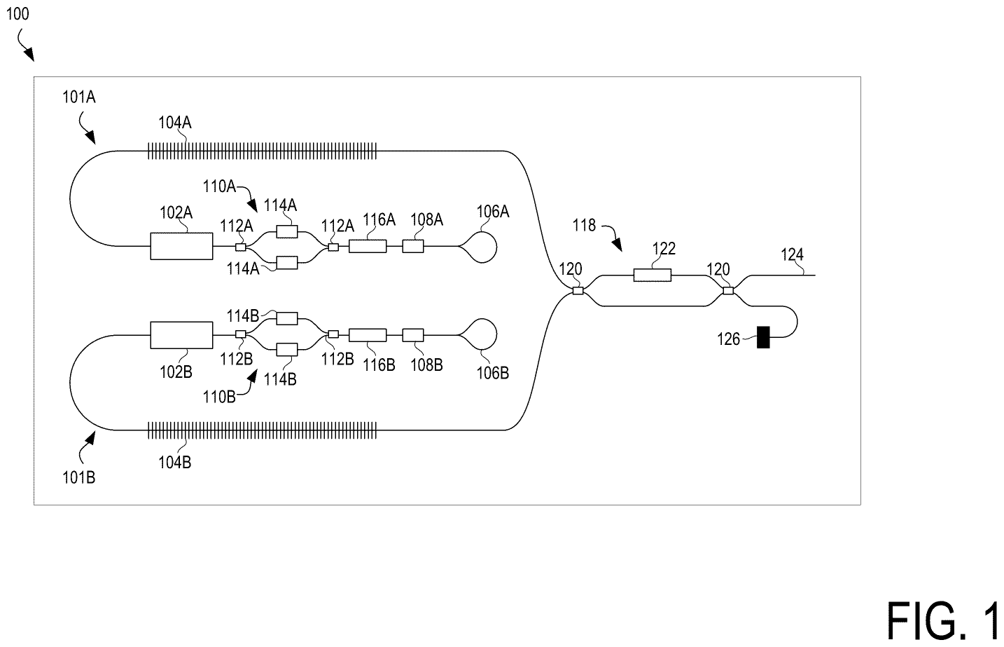

Referring now to FIG. 1, in one embodiment, a photonic integrated circuit (PIC) die 100 includes lasers 101A, 101B and a switch 118. Each laser 101A, 101B includes an amplifier 102, a sampled Bragg grating 104, a loop mirror 106, a thermal phase shifter 108, an interferometer 110 to select a wavelength for the corresponding laser 101A, 101B, and a PN junction phase shifter 116 connected by waveguides. The linewidth of each laser 101A, 101B is relatively narrow, such as less than 5-40 kilohertz.

The amplifier 102 amplifies the light reflected by the Bragg grating 104 and the loop mirror 106. The amplifier 102 may be any suitable amplifier, such as, but not limited to, an O-band (about 1260-1360 nanometers) or C-band (about 1530-1565 nanometers) semiconductor optical amplifier. The amplifier 102 may drive the output of the laser to any suitable power level, such as 0-20 dBm. In an illustrative embodiment, the output of the laser 101 is about 10 dBm. The sampled Bragg grating 104 has multiple reflectivity peaks, allowing for the laser 101 to have several possible wavelengths. The sampled Bragg grating 104 may have any suitable spacing between peaks, such as 50-2,000 gigahertz, and may have any suitable bandwidth in each peak, such as 1-20 gigahertz. The sampled Bragg grating 104 may have any suitable number of reflectivity peaks, such as 2-40 peaks.

The interferometer 110 is an unbalanced Mach-Zehnder interferometer 110 with two splitters 112 and two phase shifters 114. The phase shifters 114 can tune the Mach-Zehnder to transmit light at a selected reflectivity peak of the Bragg grating 104, selecting the wavelength of the laser 101. The interferometers may be able to tune over any suitable number of reflectivity peaks of the Bragg grating 104, such as 2-40 peaks, in a non-limiting example. In an illustrative embodiment, the phase shifters 114 are thermal phase shifters 114 that operate by heating up the waveguide in one arm of the interferometer 110. Additionally or alternatively, the phase shifters 114 may be another phase shifter type, such as a PN junction phase shifter. In some embodiments, the interferometer 110 may have a phase shifter 114 only in one arm. The splitters 112 may be any suitable splitters 112, such as multi-mode interferometers, Y-splitters, directional couplers, etc.

The thermal phase shifter 108 tunes the overall length of the cavity of the laser 101. The PN junction phase shifter 116 can rapidly tune the frequency of the laser, linearly chirping the laser. The PN junction phase shifter 116 can chirp the laser over a range of, e.g., 1-10 gigahertz. The PN junction phase shifter 116 may use any suitable free-carrier-dispersion-based phase shifting techniques, including carrier injection, carrier depletion, and carrier accumulation.

In one embodiment, the switch 118 is a balanced Mach-Zehnder interferometer with splitters 120 and a phase shifter 122. The splitters 120 may be similar to the splitters 112, and the phase shifter 122 may be similar to the phase shifter 116. The phase shifter 122 may be able to change phase in, e.g., 1 nanosecond, allowing for fast switching time. In general, the switch 118 may be able to switch in less than, e.g., 1-500 nanoseconds. The inputs to the switch 118 are the outputs of the two lasers 101A, 101B, and the outputs of the switch 118 are an output 124 for the PIC die 100 and a light dump 126.

The PIC die 100 may be made of any suitable material, such as silicon. In the illustrative embodiment, waveguides for the lasers 101 may be silicon waveguides embedded in silicon oxide cladding. In some embodiments, the PIC die 100 may include other materials, such as silicon nitride waveguides, a III-V semiconductor material, silicon or other semiconductors doped with silicon, etc. The PIC die 100 may include, e.g., gallium, arsenic, indium, phosphorous, germanium, erbium, etc. Other optical components, such as optical fibers and/or optical interposers, may be connected to the PIC die 100 to provide optical signals into and out of the waveguides of the PIC die 100. In addition to the lasers 101, the PIC die 100 may include active or passive optical elements such as splitters, couplers, filters, optical amplifiers, lasers, photodetectors, modulators, etc. The PIC die 100 may include additional components, such as traces of copper or other conductors connected to active components such as the phase shifters 114, 116, 108, 122, the amplifiers 102, etc. The PIC die 100 may have any suitable length or width, such as 1-300 millimeters. The PIC die 100 may have any suitable thickness, such as 0.05-5 millimeters.

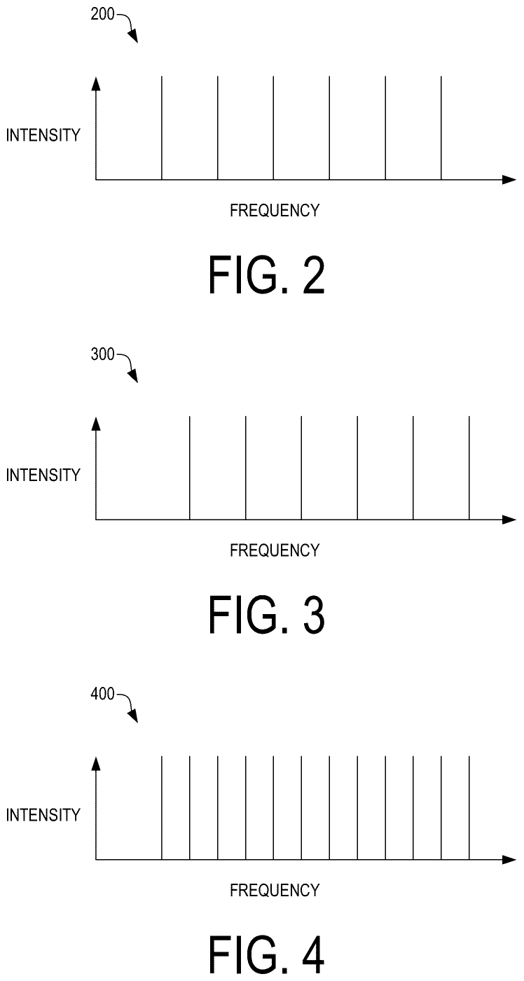

Referring now to FIGS. 2-4, graphs show the output frequencies for the lasers 101A, 101B. Plot 200 in FIG. 2 shows possible output frequencies from one embodiment of the laser 101A. Plot 300 in FIG. 3 shows possible output frequencies from one embodiment of the lasers 101B. Plot 400 in FIG. 4 shows possible output frequencies from the output 124 of the switch 118, which is a combination of the possible output frequencies from the lasers 101A, 101B. In the illustrative embodiment, each lasers 101A, 101B can select from six comb lines of the Bragg grating 104A, 104B for a possible output. In other embodiments, the lasers 101A, 101B may select from any suitable number of comb lines, such as 2-20.

In use, one of the lasers 101, such as laser 101A, is selected for output. The phase shifter 116A linearly chirps the frequency of the laser 101A over a range of, e.g., 5 gigahertz over a time period of, e.g., 40 microseconds. While the laser 101A is selected for output, the wavelength of the laser 101B can be changed to a desired reflectivity peak of the Bragg grating by tuning the thermal phase shifters 114B, 108B. It may take, e.g., 2-20 microseconds for the thermal phase shifters 114B, 108B to fully stabilize. As a result, it may take that amount of time for the laser 101B to fully stabilize. As laser 101A is selected for output while laser 101B is stabilizing, the temporarily unstable output of laser 101B is directed by the switch 118 to the dump 126 and does not impact the overall performance of laser output from the PIC die 100.

After laser 101B is stabilized and laser 101A has completed a chirp process, the switch 118 switches the output from the laser 101A to the laser 101B. The output of laser 101B can then be chirped while the frequency of laser 101A can be tuned to another reflectivity peak of the Bragg grating 104A. This process can repeat, providing narrow-linewidth light at multiple possible frequencies that can be linearly chirped.

The PIC die 100 described above provides several advantages. Because each laser 101 is unused for tens of microseconds, the lasers 101 have time to stabilize, reducing the risk of mode hops and greatly improving chirp linearity. Additionally, because there is so much time to stabilize, relatively slow thermal phase shifters 114 can be used to switch the laser 101 wavelength, reducing cavity loss by up to 12 dB. The extended cavity of the lasers 101 provides for a narrow linewidth. The lasers 101 can select between several reflectivity peaks, allowing for a large number of lasers frequencies with a small footprint and number of components. Additionally, the presence of two lasers increases the spacing between the reflectivity peaks for the Bragg gratings 104, simplifying channel selector design.

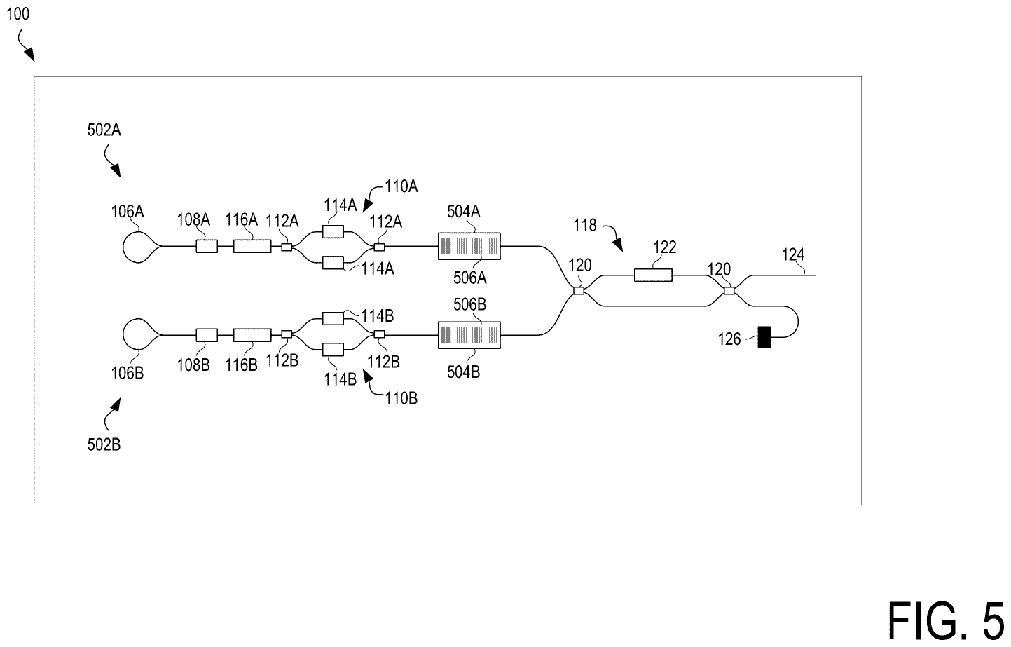

It should be appreciated that the design described above is merely one possible embodiment, and additional embodiments are envisioned. For example, referring now to FIG. 5, in one embodiment, a PIC die 100 includes lasers 502A, 502B. In the lasers 502, a sampled Bragg grating 506 is placed in the gain section 504, forming extended cavity distributed feedback lasers 502. The other components may be similar or identical to those described above in regard to the lasers 101, a description of which will not be repeated in the interest of clarity.

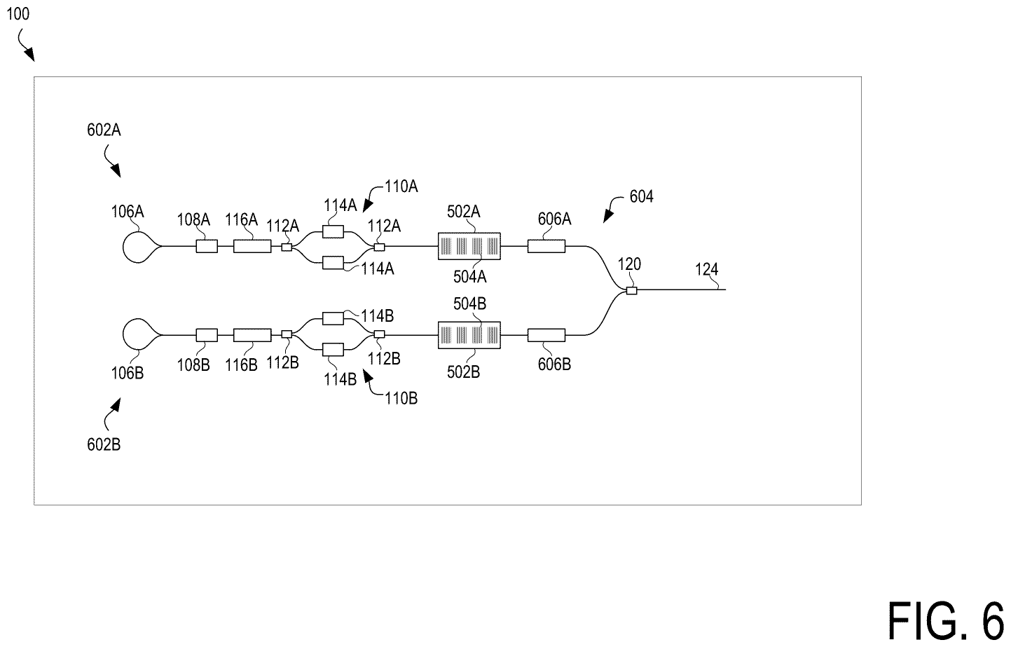

In another example, referring now to FIG. 6, in one embodiment, a PIC die 100 includes lasers 602A, 602B. The light from the lasers 602 can be switched using a switch 604. The switch 604 includes two amplifiers 606A, 606B and a splitter 120, such as an MMI combiner. The amplifiers 606 can either amplify/pass the light from the lasers 602 or can absorb the light from the lasers 602, allowing for the light of one of the lasers to be transmitted to the splitter 120. The other components may be similar or identical to those described above in regard to the lasers 101 and 502, a description of which will not be repeated in the interest of clarity.

It should be appreciated that various components described above may be implemented in various ways. For example, the lasers may be combined using, e.g., add/drop ring filters, array waveguide gratings (AWG), Echelle gratings, etc. Instead of or in addition to using sampled gratings and/or unbalanced Mach-Zehnder interferometer filters, other types of intracavity filters may be used, such as ring resonators. In general, any suitable type of filter, reflector, phase shifter, switch, etc., may be used to implement the approach described above.

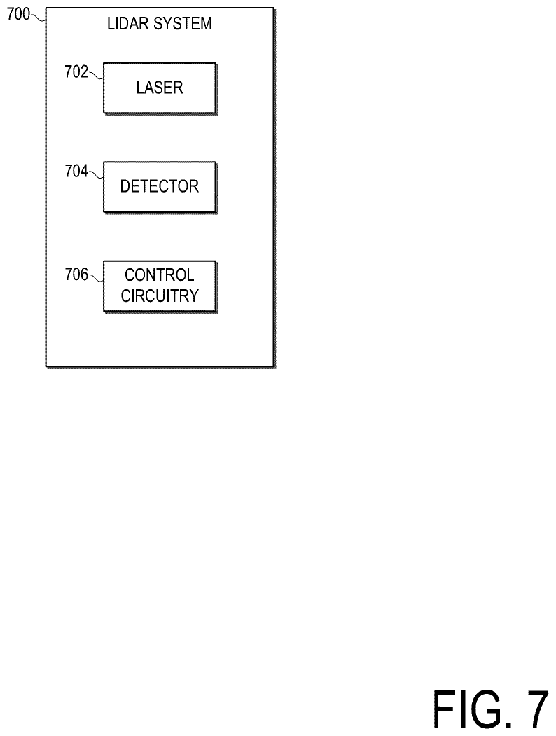

Referring now to FIG. 7, in one embodiment, a lidar system 700 includes a laser 702, a detector 704, and control circuitry 706. Some of the modules of the lidar system 700, such as the control circuitry 706, may be embodied as hardware, software, firmware, or a combination thereof. For example, the various modules, logic, and other components of the lidar system 700 may form a portion of, or otherwise be established by, a processor, memory, data storage, or other hardware components of a computing device, such as the electrical device 1300 described below. The lidar system 700 may be embodied as a system-on-a-chip or a system-on-a-package. Such a system or package may include one or more electronic integrated circuit (EIC) dies and/or one or more PIC dies, such as any suitable embodiment of the PIC dies 100 described above. For example, in one embodiment, the laser 702 and the detector 704 may be packaged together in one package or may be embodied in one PIC die. The control circuitry 706 may be embodied as one or more EIC dies communicatively coupled to and/or packaged with the one or more PIC dies embodying the laser 702 and the detector 704.

In some embodiments, one or more of the modules of the lidar system 700 may be embodied as circuitry or collection of electrical devices (e.g., laser circuitry 702, detector circuitry 704, control circuitry 706, etc.). It should be appreciated that, in such embodiments, one or more of the circuits (e.g., the laser circuitry 702, the detector circuitry 704, the control circuitry 706, etc.) may form a portion of one or more of the processor, the memory, the data storage and/or other components of a computing device. For example, in some embodiments, some or all of the modules may be embodied as or include a processor as well as memory and/or data storage storing instructions to be executed by the processor. Additionally, in some embodiments, one or more of the illustrative modules may form a portion of another module and/or one or more of the illustrative modules may be independent of one another. Further, in some embodiments, one or more of the modules of the lidar system 700 may be embodied as virtualized hardware components or emulated architecture, which may be established and maintained by the processor or other components of a computing device. It should be appreciated that some of the functionality of one or more of the modules of the lidar system 700 may require a hardware implementation, in which case embodiments of modules that implement such functionality will be embodied at least partially as hardware.

The laser 702 may include any suitable or combination of lasers, such as the lasers 101, 502, 602, etc. The laser 702 may emit a laser signal suitable for use with a lidar system, such as a frequency-modulated continuous-wave (FMCW) laser. The lidar system 700 may include components to scan the laser 702 in any suitable direction at any suitable rate.

The detector 704 includes one or more photodetectors to detect light of the laser 702 reflected/scattered from the environment. The detector 704 may include photodetectors in one or more PIC dies. In some embodiments, the photodetectors of the detector 704 may be on the same PIC die 100 as the lasers 101, 502, 602 of the lidar system 700. In some embodiments, the detector 704 may use homodyne detection with the output of the laser 702 used as a local oscillator to detect phase and amplitude information of the reflected signal from the environment.

The control circuitry 706, which may be embodied as hardware, firmware, software, virtualized hardware, emulated architecture, and/or a combination thereof as discussed above, is configured to control the laser 702 and detector 704 and process information from the detector 704. The control circuitry 706 may control the components of the laser 702 and photodetector 704, including various switches 118, 604, phase shifters 108, 116, 114, amplifiers 102, 504, 606. The control circuitry 706 may process information from the detector 704 to determine the direction and distance to various objects and their speed. In some embodiments, the control circuitry 706 may perform object detection and identification, map a scene, determine an action for an autonomous vehicle to take to avoid an object, etc. Additionally or alternatively, the control circuitry 706 may communicate information from or information derived from the detector 704 to another component, such as a local processor or remote computing device.

The lidar system 700 may be included in any suitable system or used in any suitable environment. For example, the lidar system 700 may be applied for autonomous vehicles, 3D mapping, air traffic control, surveying, mining, agriculture, metrology, etc.

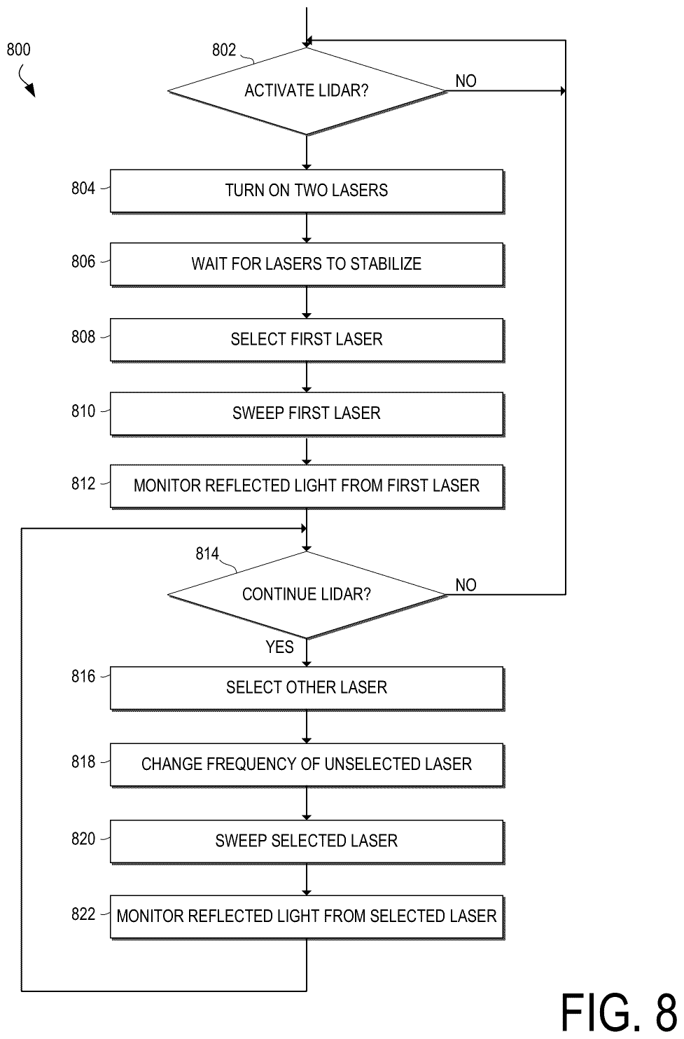

Referring now to FIG. 8, in one embodiment, a flowchart for a method 800 for operating a lidar system 700. The method 800 may be executed by a computing device, such as the control circuitry 706 and/or the electrical device 1300. The method 800 is described as being performed or controlled by the control circuitry 706. It should be appreciated that, in some embodiments, other components or combinations of components may perform some or all of the steps of the method 800.

The method 800 begins in block 802, in which the control circuitry 706 determines whether or not to activate the lidar system 700. For example, the control circuitry 706 may wait for a command from a user or wait for communication from a remote compute device to start the lidar system 700. If the control circuitry 706 determines not to activate the lidar system, the method 800 loops back to block 802 to again determine whether or not to activate the lidar system 700. If the control circuitry 706 determines to activate the lidar system 700, the method 800 proceeds to block 804.

In block 804, the control circuitry 706 turns on two lasers, such as lasers 101A and 101B. The control circuitry 706 may control the amplifiers 102, phase shifters 114, 108, 116, 122, and other components of the lasers 101. The control circuitry 706 may select an initial reflective peak for the Bragg gratings 104 for each laser 101. In block 806, the control circuitry 706 may wait for the lasers 101 to stabilize. After initial start-up, the lasers 101 may stabilize after a wavelength change within, e.g., 10 microseconds. In some embodiments, the lasers 101 may take longer to stabilize on start-up, such as hundreds of microseconds to seconds. In other embodiments, the lasers 101 may stabilize on initial start-up within, e.g., 10 microseconds.

In block 808, the control circuitry 706 selects the first laser 101A by controlling the switch 118. In block 810, the control circuitry 706 sweeps the frequency of the first laser 101A by controlling the PN junction phase shifter 116. The control circuitry 706 may sweep the frequency of the laser 101A one or more times by any suitable amount, such as 1-10 gigahertz, and over any suitable period of time, such as 5-100 microseconds. In an illustrative embodiment, the control circuitry 706 sweeps the frequency of the laser 101A by 5 gigahertz over a period of 40 microseconds.

In block 812, the control circuitry 706 monitors light from the first laser 101A that is reflected by the environment using the detector 704. The control circuitry 706 may, e.g., determine a direction and distance to one or more objects, perform object detection, determine object speed, send data from or data derived from the detector 704 to another component for processing, etc.

In block 814, the control circuitry 706 determines whether or not to continue operation of the lidar system 700. If the control circuitry 706 determines not to continue operation of the lidar system 700, the method 800 loops back to block 802 to determine whether the lidar system 700 should be activated. If the control circuitry 706 determines to continue operation of the lidar system 700, the method 800 proceeds to block 816.

In block 816, the control circuitry 706 selects the other laser for output. For example, if the laser 101A is currently selected, the control circuitry 706 controls the switch 118 to select the laser 101B. Conversely, if the laser 101B is currently selected, the control circuitry 706 controls the switch 118 to select the laser 101A. As the other laser has had time to stabilize while the previous laser was swept, the output of the other laser will be stable.

In block 818, the control circuitry 706 changes the frequency of the unselected laser. In an illustrative embodiment, the control circuitry 706 controls the phase shifter 114 of the interferometer 110 of the unselected laser to operate the laser 101 at a different reflective peak of the Bragg grating 104. The control circuitry 706 may select the new reflective peak of the Bragg grating 104 in any suitable manner, such as by cycling between 2-10 peaks.

In block 820, the control circuitry 706 sweeps the frequency of the selected laser in a similar manner as in block 810. In block 822, the control circuitry 706 monitors the light from the selected laser that is reflected by the environment in a similar manner as in block 812. The method 800 then loops back to block 814 to determine whether the lidar system 700 should continue operation.

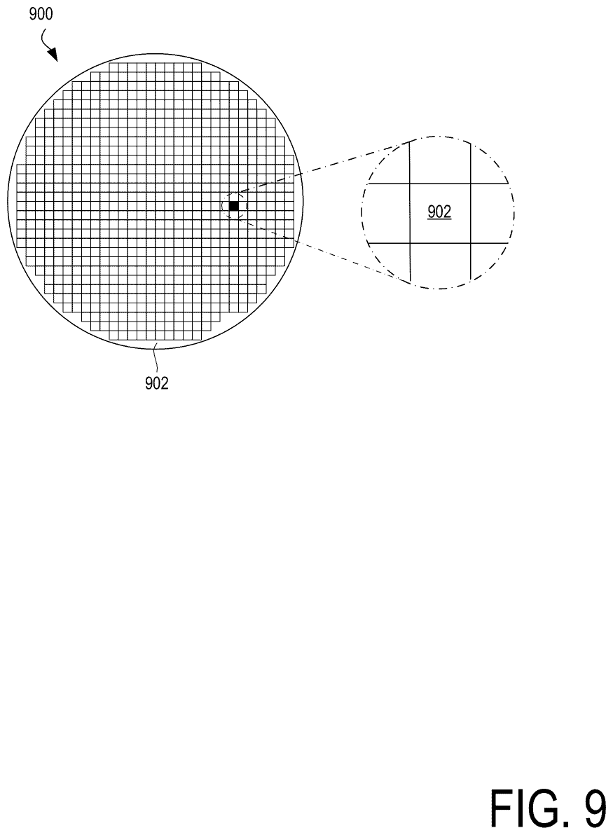

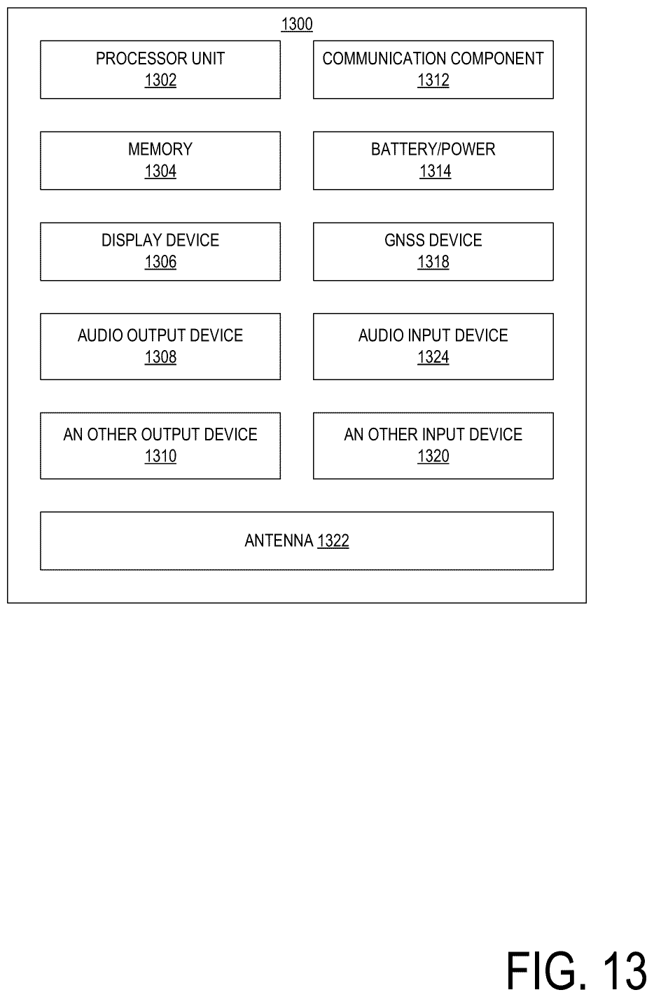

FIG. 9 is a top view of a wafer 900 and dies 902 that may be included in any of the systems 700 disclosed herein (e.g., as any suitable ones of the dies 100). The wafer 900 may be composed of semiconductor material and may include one or more dies 902 having integrated circuit structures formed on a surface of the wafer 900. The individual dies 902 may be a repeating unit of an integrated circuit product that includes any suitable integrated circuit. After the fabrication of the semiconductor product is complete, the wafer 900 may undergo a singulation process in which the dies 902 are separated from one another to provide discrete “chips” of the integrated circuit product. The die 902 may be any of the dies 100 disclosed herein. The die 902 may include one or more transistors (e.g., some of the transistors 1040 of FIG. 10, discussed below), supporting circuitry to route electrical signals to the transistors, passive components (e.g., signal traces, resistors, capacitors, or inductors), and/or any other integrated circuit components. In some embodiments, the wafer 900 or the die 902 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 902. For example, a memory array formed by multiple memory devices may be formed on a same die 902 as a processor unit (e.g., the processor unit 1302 of FIG. 13) or other logic that is configured to store information in the memory devices or execute instructions stored in the memory array. Various ones of the systems 700 disclosed herein may be manufactured using a die-to-wafer assembly technique in which some dies 100 are attached to a wafer 900 that include others of the dies 100, and the wafer 900 is subsequently singulated.

FIG. 10 is a cross-sectional side view of an integrated circuit device 1000 that may be included in any of the systems 700 disclosed herein (e.g., in any of the dies 100). One or more of the integrated circuit devices 1000 may be included in one or more dies 902 (FIG. 9). The integrated circuit device 1000 may be formed on a die substrate 1002 (e.g., the wafer 900 of FIG. 9) and may be included in a die (e.g., the die 902 of FIG. 9). The die substrate 1002 may be a semiconductor substrate composed of semiconductor material systems including, for example, n-type or p-type materials systems (or a combination of both). The die substrate 1002 may include, for example, a crystalline substrate formed using a bulk silicon or a silicon-on-insulator (SOI) substructure. In some embodiments, the die substrate 1002 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1002. Although a few examples of materials from which the die substrate 1002 may be formed are described here, any material that may serve as a foundation for an integrated circuit device 1000 may be used. The die substrate 1002 may be part of a singulated die (e.g., the dies 902 of FIG. 9) or a wafer (e.g., the wafer 900 of FIG. 9).

The integrated circuit device 1000 may include one or more device layers 1004 disposed on the die substrate 1002. The device layer 1004 may include features of one or more transistors 1040 (e.g., metal oxide semiconductor field-effect transistors (MOSFETs)) formed on the die substrate 1002. The transistors 1040 may include, for example, one or more source and/or drain (S/D) regions 1020, a gate 1022 to control current flow between the S/D regions 1020, and one or more S/D contacts 1024 to route electrical signals to/from the S/D regions 1020. The transistors 1040 may include additional features not depicted for the sake of clarity, such as device isolation regions, gate contacts, and the like. The transistors 1040 are not limited to the type and configuration depicted in FIG. 10 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

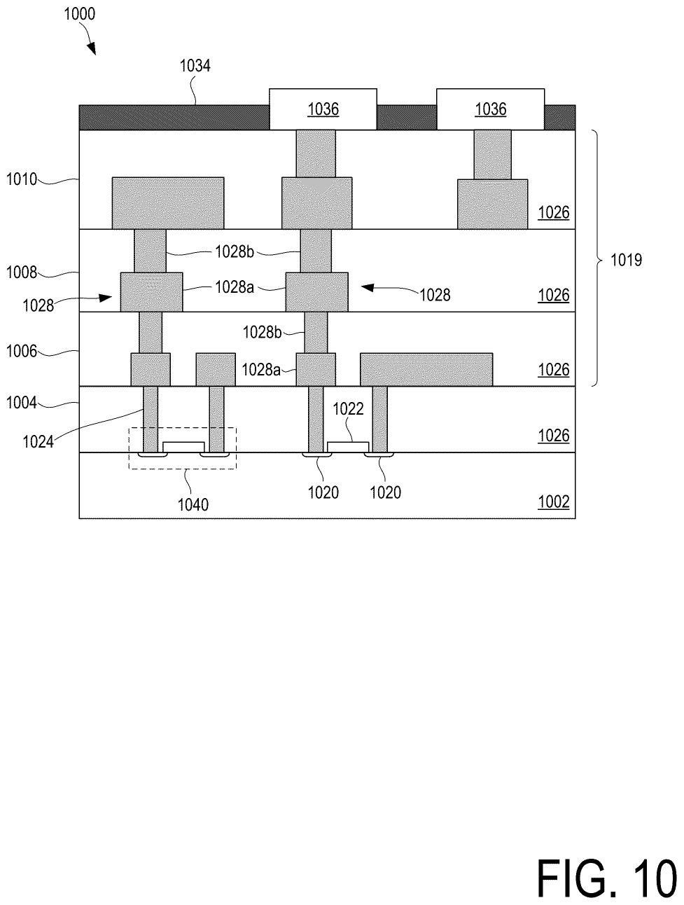

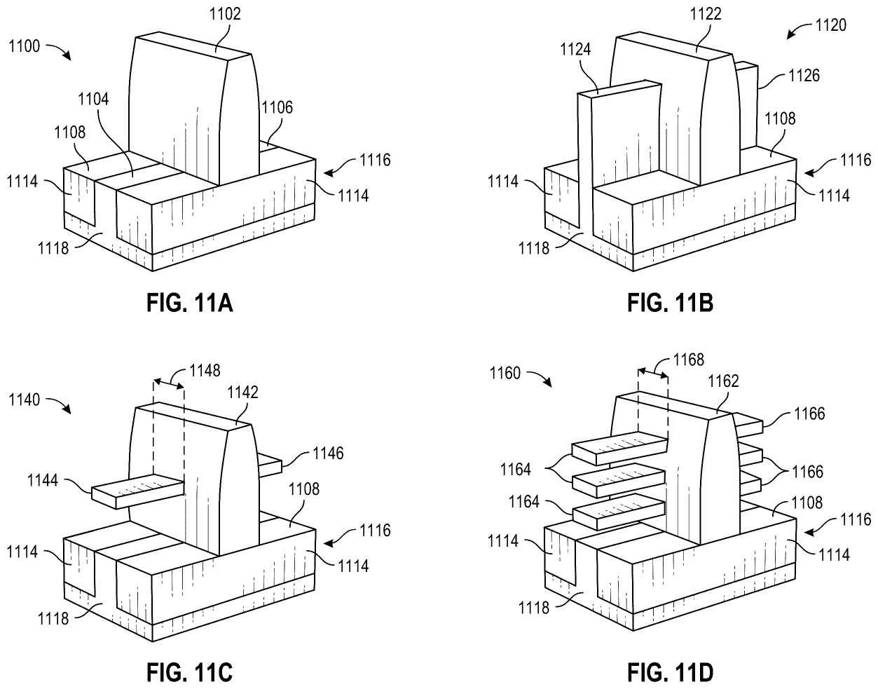

FIGS. 11A-11D are simplified perspective views of example planar, FinFET, gate-all-around, and stacked gate-all-around transistors. The transistors illustrated in FIGS. 11A-11D are formed on a substrate 1116 having a surface 1108. Isolation regions 1114 separate the source and drain regions of the transistors from other transistors and from a bulk region 1118 of the substrate 1116.

FIG. 11A is a perspective view of an example planar transistor 1100 comprising a gate 1102 that controls current flow between a source region 1104 and a drain region 1106. The transistor 1100 is planar in that the source region 1104 and the drain region 1106 are planar with respect to the substrate surface 1108.

FIG. 11B is a perspective view of an example FinFET transistor 1120 comprising a gate 1122 that controls current flow between a source region 1124 and a drain region 1126. The transistor 1120 is non-planar in that the source region 1124 and the drain region 1126 comprise “fins” that extend upwards from the substrate surface 1128. As the gate 1122 encompasses three sides of the semiconductor fin that extends from the source region 1124 to the drain region 1126, the transistor 1120 can be considered a tri-gate transistor. FIG. 11B illustrates one S/D fin extending through the gate 1122, but multiple S/D fins can extend through the gate of a FinFET transistor.

FIG. 11C is a perspective view of a gate-all-around (GAA) transistor 1140 comprising a gate 1142 that controls current flow between a source region 1144 and a drain region 1146. The transistor 1140 is non-planar in that the source region 1144 and the drain region 1146 are elevated from the substrate surface 1128.

FIG. 11D is a perspective view of a GAA transistor 1160 comprising a gate 1162 that controls current flow between multiple elevated source regions 1164 and multiple elevated drain regions 1166. The transistor 1160 is a stacked GAA transistor as the gate controls the flow of current between multiple elevated S/D regions stacked on top of each other. The transistors 1140 and 1160 are considered gate-all-around transistors as the gates encompass all sides of the semiconductor portions that extends from the source regions to the drain regions. The transistors 1140 and 1160 can alternatively be referred to as nanowire, nanosheet, or nanoribbon transistors depending on the width (e.g., widths 1148 and 1168 of transistors 1140 and 1160, respectively) of the semiconductor portions extending through the gate.

Returning to FIG. 10, a transistor 1040 may include a gate 1022 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1040 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1040 along the source-channel-drain direction, the gate electrode may consist of a U-shaped structure that includes a bottom portion substantially parallel to the surface of the die substrate 1002 and two sidewall portions that are substantially perpendicular to the top surface of the die substrate 1002. In other embodiments, at least one of the metal layers that form the gate electrode may simply be a planar layer that is substantially parallel to the top surface of the die substrate 1002 and does not include sidewall portions substantially perpendicular to the top surface of the die substrate 1002. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1020 may be formed within the die substrate 1002 adjacent to the gate 1022 of individual transistors 1040. The S/D regions 1020 may be formed using an implantation/diffusion process or an etching/deposition process, for example. In the former process, dopants such as boron, aluminum, antimony, phosphorous, or arsenic may be ion-implanted into the die substrate 1002 to form the S/D regions 1020. An annealing process that activates the dopants and causes them to diffuse farther into the die substrate 1002 may follow the ion-implantation process. In the latter process, the die substrate 1002 may first be etched to form recesses at the locations of the S/D regions 1020. An epitaxial deposition process may then be carried out to fill the recesses with material that is used to fabricate the S/D regions 1020. In some implementations, the S/D regions 1020 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1020 may be formed using one or more alternate semiconductor materials such as germanium or a group III-V material or alloy. In further embodiments, one or more layers of metal and/or metal alloys may be used to form the S/D regions 1020.

Electrical signals, such as power and/or input/output (I/O) signals, may be routed to and/or from the devices (e.g., transistors 1040) of the device layer 1004 through one or more interconnect layers disposed on the device layer 1004 (illustrated in FIG. 10 as interconnect layers 1006-1010). For example, electrically conductive features of the device layer 1004 (e.g., the gate 1022 and the S/D contacts 1024) may be electrically coupled with the interconnect structures 1028 of the interconnect layers 1006-1010. The one or more interconnect layers 1006-1010 may form a metallization stack (also referred to as an “ILD stack”) 1019 of the integrated circuit device 1000.

The interconnect structures 1028 may be arranged within the interconnect layers 1006-1010 to route electrical signals according to a wide variety of designs; in particular, the arrangement is not limited to the particular configuration of interconnect structures 1028 depicted in FIG. 10. Although a particular number of interconnect layers 1006-1010 is depicted in FIG. 10, embodiments of the present disclosure include integrated circuit devices having more or fewer interconnect layers than depicted.

In some embodiments, the interconnect structures 1028 may include lines 1028a and/or vias 1028b filled with an electrically conductive material such as a metal. The lines 1028a may be arranged to route electrical signals in a direction of a plane that is substantially parallel with a surface of the die substrate 1002 upon which the device layer 1004 is formed. For example, the lines 1028a may route electrical signals in a direction in and out of the page and/or in a direction across the page. The vias 1028b may be arranged to route electrical signals in a direction of a plane that is substantially perpendicular to the surface of the die substrate 1002 upon which the device layer 1004 is formed. In some embodiments, the vias 1028b may electrically couple lines 1028a of different interconnect layers 1006-1010 together.

The interconnect layers 1006-1010 may include a dielectric material 1026 disposed between the interconnect structures 1028, as shown in FIG. 10. In some embodiments, dielectric material 1026 disposed between the interconnect structures 1028 in different ones of the interconnect layers 1006-1010 may have different compositions; in other embodiments, the composition of the dielectric material 1026 between different interconnect layers 1006-1010 may be the same. The device layer 1004 may include a dielectric material 1026 disposed between the transistors 1040 and a bottom layer of the metallization stack as well. The dielectric material 1026 included in the device layer 1004 may have a different composition than the dielectric material 1026 included in the interconnect layers 1006-1010; in other embodiments, the composition of the dielectric material 1026 in the device layer 1004 may be the same as a dielectric material 1026 included in any one of the interconnect layers 1006-1010.

A first interconnect layer 1006 (referred to as Metal 1 or “M1”) may be formed directly on the device layer 1004. In some embodiments, the first interconnect layer 1006 may include lines 1028a and/or vias 1028b, as shown. The lines 1028a of the first interconnect layer 1006 may be coupled with contacts (e.g., the S/D contacts 1024) of the device layer 1004. The vias 1028b of the first interconnect layer 1006 may be coupled with the lines 1028a of a second interconnect layer 1008.

The second interconnect layer 1008 (referred to as Metal 2 or “M2”) may be formed directly on the first interconnect layer 1006. In some embodiments, the second interconnect layer 1008 may include via 1028b to couple the lines 1028 of the second interconnect layer 1008 with the lines 1028a of a third interconnect layer 1010. Although the lines 1028a and the vias 1028b are structurally delineated with a line within individual interconnect layers for the sake of clarity, the lines 1028a and the vias 1028b may be structurally and/or materially contiguous (e.g., simultaneously filled during a dual-damascene process) in some embodiments.

The third interconnect layer 1010 (referred to as Metal 3 or “M3”) (and additional interconnect layers, as desired) may be formed in succession on the second interconnect layer 1008 according to similar techniques and configurations described in connection with the second interconnect layer 1008 or the first interconnect layer 1006. In some embodiments, the interconnect layers that are “higher up” in the metallization stack 1019 in the integrated circuit device 1000 (i.e., farther away from the device layer 1004) may be thicker that the interconnect layers that are lower in the metallization stack 1019, with lines 1028a and vias 1028b in the higher interconnect layers being thicker than those in the lower interconnect layers.

The integrated circuit device 1000 may include a solder resist material 1034 (e.g., polyimide or similar material) and one or more conductive contacts 1036 formed on the interconnect layers 1006-1010. In FIG. 10, the conductive contacts 1036 are illustrated as taking the form of bond pads. The conductive contacts 1036 may be electrically coupled with the interconnect structures 1028 and configured to route the electrical signals of the transistor(s) 1040 to external devices. For example, solder bonds may be formed on the one or more conductive contacts 1036 to mechanically and/or electrically couple an integrated circuit die including the integrated circuit device 1000 with another component (e.g., a printed circuit board). The integrated circuit device 1000 may include additional or alternate structures to route the electrical signals from the interconnect layers 1006-1010; for example, the conductive contacts 1036 may include other analogous features (e.g., posts) that route the electrical signals to external components.

In some embodiments in which the integrated circuit device 1000 is a double-sided die, the integrated circuit device 1000 may include another metallization stack (not shown) on the opposite side of the device layer(s) 1004. This metallization stack may include multiple interconnect layers as discussed above with reference to the interconnect layers 1006-1010, to provide conductive pathways (e.g., including conductive lines and vias) between the device layer(s) 1004 and additional conductive contacts (not shown) on the opposite side of the integrated circuit device 1000 from the conductive contacts 1036.

In other embodiments in which the integrated circuit device 1000 is a double-sided die, the integrated circuit device 1000 may include one or more through silicon vias (TSVs) through the die substrate 1002; these TSVs may make contact with the device layer(s) 1004, and may provide conductive pathways between the device layer(s) 1004 and additional conductive contacts (not shown) on the opposite side of the integrated circuit device 1000 from the conductive contacts 1036. In some embodiments, TSVs extending through the substrate can be used for routing power and ground signals from conductive contacts on the opposite side of the integrated circuit device 1000 from the conductive contacts 1036 to the transistors 1040 and any other components integrated into the die 1000, and the metallization stack 1019 can be used to route I/O signals from the conductive contacts 1036 to transistors 1040 and any other components integrated into the die 1000.

Multiple integrated circuit devices 1000 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

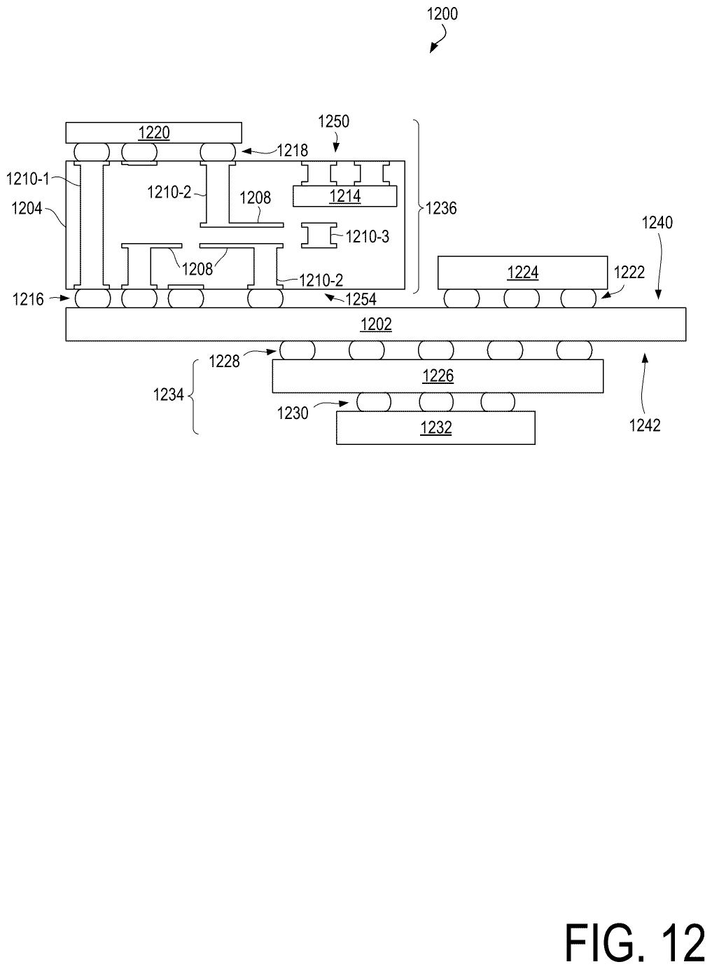

FIG. 12 is a cross-sectional side view of an integrated circuit device assembly 1200 that may include any of the systems 700 or dies 100 disclosed herein. In some embodiments, the integrated circuit device assembly 1200 may be a lidar system 700. The integrated circuit device assembly 1200 includes a number of components disposed on a circuit board 1202 (which may be a motherboard, system board, mainboard, etc.). The integrated circuit device assembly 1200 includes components disposed on a first face 1240 of the circuit board 1202 and an opposing second face 1242 of the circuit board 1202; generally, components may be disposed on one or both faces 1240 and 1242. Any of the integrated circuit components discussed below with reference to the integrated circuit device assembly 1200 may take the form of any suitable ones of the embodiments of the system 700 or die 100 disclosed herein.

In some embodiments, the circuit board 1202 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1202. In other embodiments, the circuit board 1202 may be a non-PCB substrate. The integrated circuit device assembly 1200 illustrated in FIG. 12 includes a package-on-interposer structure 1236 coupled to the first face 1240 of the circuit board 1202 by coupling components 1216. The coupling components 1216 may electrically and mechanically couple the package-on-interposer structure 1236 to the circuit board 1202, and may include solder balls (as shown in FIG. 12), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1236 may include an integrated circuit component 1220 coupled to an interposer 1204 by coupling components 1218. The coupling components 1218 may take any suitable form for the application, such as the forms discussed above with reference to the coupling components 1216. Although a single integrated circuit component 1220 is shown in FIG. 12, multiple integrated circuit components may be coupled to the interposer 1204; indeed, additional interposers may be coupled to the interposer 1204. The interposer 1204 may provide an intervening substrate used to bridge the circuit board 1202 and the integrated circuit component 1220.

The integrated circuit component 1220 may be a packaged or unpacked integrated circuit product that includes one or more integrated circuit dies (e.g., the die 902 of FIG. 9, the integrated circuit device 1000 of FIG. 10) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1220, a single monolithic integrated circuit die comprises solder bumps attached to contacts on the die. The solder bumps allow the die to be directly attached to the interposer 1204. The integrated circuit component 1220 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1220 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1220 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1220 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1204 may spread connections to a wider pitch or reroute a connection to a different connection. For example, the interposer 1204 may couple the integrated circuit component 1220 to a set of ball grid array (BGA) conductive contacts of the coupling components 1216 for coupling to the circuit board 1202. In the embodiment illustrated in FIG. 12, the integrated circuit component 1220 and the circuit board 1202 are attached to opposing sides of the interposer 1204; in other embodiments, the integrated circuit component 1220 and the circuit board 1202 may be attached to a same side of the interposer 1204. In some embodiments, three or more components may be interconnected by way of the interposer 1204.

In some embodiments, the interposer 1204 may be formed as a PCB, including multiple metal layers separated from one another by layers of dielectric material and interconnected by electrically conductive vias. In some embodiments, the interposer 1204 may be formed of an epoxy resin, a fiberglass-reinforced epoxy resin, an epoxy resin with inorganic fillers, a ceramic material, or a polymer material such as polyimide. In some embodiments, the interposer 1204 may be formed of alternate rigid or flexible materials that may include the same materials described above for use in a semiconductor substrate, such as silicon, germanium, and other group III-V and group IV materials. The interposer 1204 may include metal interconnects 1208 and vias 1210, including but not limited to through hole vias 1210-1 (that extend from a first face 1250 of the interposer 1204 to a second face 1254 of the interposer 1204), blind vias 1210-2 (that extend from the first or second faces 1250 or 1254 of the interposer 1204 to an internal metal layer), and buried vias 1210-3 (that connect internal metal layers).

In some embodiments, the interposer 1204 can comprise a silicon interposer. Through silicon vias (TSV) extending through the silicon interposer can connect connections on a first face of a silicon interposer to an opposing second face of the silicon interposer. In some embodiments, an interposer 1204 comprising a silicon interposer can further comprise one or more routing layers to route connections on a first face of the interposer 1204 to an opposing second face of the interposer 1204.

The interposer 1204 may further include embedded devices 1214, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1204. The package-on-interposer structure 1236 may take the form of any of the package-on-interposer structures known in the art.

The integrated circuit device assembly 1200 may include an integrated circuit component 1224 coupled to the first face 1240 of the circuit board 1202 by coupling components 1222. The coupling components 1222 may take the form of any of the embodiments discussed above with reference to the coupling components 1216, and the integrated circuit component 1224 may take the form of any of the embodiments discussed above with reference to the integrated circuit component 1220.

The integrated circuit device assembly 1200 illustrated in FIG. 12 includes a package-on-package structure 1234 coupled to the second face 1242 of the circuit board 1202 by coupling components 1228. The package-on-package structure 1234 may include an integrated circuit component 1226 and an integrated circuit component 1232 coupled together by coupling components 1230 such that the integrated circuit component 1226 is disposed between the circuit board 1202 and the integrated circuit component 1232. The coupling components 1228 and 1230 may take the form of any of the embodiments of the coupling components 1216 discussed above, and the integrated circuit components 1226 and 1232 may take the form of any of the embodiments of the integrated circuit component 1220 discussed above. The package-on-package structure 1234 may be configured in accordance with any of the package-on-package structures known in the art.

FIG. 13 is a block diagram of an example electrical device 1300 that may include one or more of the lidar systems 700 disclosed herein. For example, any suitable ones of the components of the electrical device 1300 may include one or more of the integrated circuit device assemblies 1200, integrated circuit components 1220, integrated circuit devices 1000, or integrated circuit dies 902 disclosed herein, and may be arranged in any of the lidar systems 700 disclosed herein. A number of components are illustrated in FIG. 13 as included in the electrical device 1300, but any one or more of these components may be omitted or duplicated, as suitable for the application. In some embodiments, some or all of the components included in the electrical device 1300 may be attached to one or more motherboards mainboards, or system boards. In some embodiments, one or more of these components are fabricated onto a single system-on-a-chip (SoC) die.

Additionally, in various embodiments, the electrical device 1300 may not include one or more of the components illustrated in FIG. 13, but the electrical device 1300 may include interface circuitry for coupling to the one or more components. For example, the electrical device 1300 may not include a display device 1306, but may include display device interface circuitry (e.g., a connector and driver circuitry) to which a display device 1306 may be coupled. In another set of examples, the electrical device 1300 may not include an audio input device 1324 or an audio output device 1308, but may include audio input or output device interface circuitry (e.g., connectors and supporting circuitry) to which an audio input device 1324 or audio output device 1308 may be coupled.

The electrical device 1300 may include one or more processor units 1302 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1302 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1300 may include a memory 1304, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1304 may include memory that is located on the same integrated circuit die as the processor unit 1302. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1300 can comprise one or more processor units 1302 that are heterogeneous or asymmetric to another processor unit 1302 in the electrical device 1300. There can be a variety of differences between the processing units 1302 in a system in terms of a spectrum of metrics of merit including architectural, microarchitectural, thermal, power consumption characteristics, and the like. These differences can effectively manifest themselves as asymmetry and heterogeneity among the processor units 1302 in the electrical device 1300.

In some embodiments, the electrical device 1300 may include a communication component 1312 (e.g., one or more communication components). For example, the communication component 1312 can manage wireless communications for the transfer of data to and from the electrical device 1300. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1312 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1312 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1312 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1312 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1312 may operate in accordance with other wireless protocols in other embodiments. The electrical device 1300 may include an antenna 1322 to facilitate wireless communications and/or to receive other wireless communications (such as AM or FM radio transmissions).

In some embodiments, the communication component 1312 may manage wired communications, such as electrical, optical, or any other suitable communication protocols (e.g., IEEE 802.3 Ethernet standards). As noted above, the communication component 1312 may include multiple communication components. For instance, a first communication component 1312 may be dedicated to shorter-range wireless communications such as Wi-Fi or Bluetooth, and a second communication component 1312 may be dedicated to longer-range wireless communications such as global positioning system (GPS), EDGE, GPRS, CDMA, WiMAX, LTE, EV-DO, or others. In some embodiments, a first communication component 1312 may be dedicated to wireless communications, and a second communication component 1312 may be dedicated to wired communications.

The electrical device 1300 may include battery/power circuitry 1314. The battery/power circuitry 1314 may include one or more energy storage devices (e.g., batteries or capacitors) and/or circuitry for coupling components of the electrical device 1300 to an energy source separate from the electrical device 1300 (e.g., AC line power).

The electrical device 1300 may include a display device 1306 (or corresponding interface circuitry, as discussed above). The display device 1306 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1300 may include an audio output device 1308 (or corresponding interface circuitry, as discussed above). The audio output device 1308 may include any embedded or wired or wirelessly connected external device that generates an audible indicator, such as speakers, headsets, or earbuds.

The electrical device 1300 may include an audio input device 1324 (or corresponding interface circuitry, as discussed above). The audio input device 1324 may include any embedded or wired or wirelessly connected device that generates a signal representative of a sound, such as microphones, microphone arrays, or digital instruments (e.g., instruments having a musical instrument digital interface (MIDI) output). The electrical device 1300 may include a Global Navigation Satellite System (GNSS) device 1318 (or corresponding interface circuitry, as discussed above), such as a Global Positioning System (GPS) device. The GNSS device 1318 may be in communication with a satellite-based system and may determine a geolocation of the electrical device 1300 based on information received from one or more GNSS satellites, as known in the art.

The electrical device 1300 may include an other output device 1310 (or corresponding interface circuitry, as discussed above). Examples of the other output device 1310 may include an audio codec, a video codec, a printer, a wired or wireless transmitter for providing information to other devices, or an additional storage device.

The electrical device 1300 may include an other input device 1320 (or corresponding interface circuitry, as discussed above). Examples of the other input device 1320 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1300 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1300 may be any other electronic device that processes data. In some embodiments, the electrical device 1300 may comprise multiple discrete physical components. Given the range of devices that the electrical device 1300 can be manifested as in various embodiments, in some embodiments, the electrical device 1300 can be referred to as a computing device or a computing system.

### EXAMPLES

Illustrative examples of the technologies disclosed herein are provided below. An embodiment of the technologies may include any one or more, and any combination of, the examples described below.

Example 1 includes a lidar system comprising a photonic integrated circuit (PIC) die comprising a first laser; and a second laser; and control circuitry to select the first laser for output; change a frequency of the second laser while the first laser is selected for output; select the second laser for output after the second laser has stabilized; and change a frequency of the first laser while the second laser is selected for output.

Example 2 includes the subject matter of Example 1, and wherein the lidar system is a frequency-modulated continuous-wave (FMCW) lidar system.

Example 3 includes the subject matter of any of Examples 1 and 2, and wherein to select the second laser for output comprises switching from the first laser to the second laser in less than 300 nanoseconds.

Example 4 includes the subject matter of any of Examples 1-3, and wherein the control circuitry is to allow the second laser to stabilize for at least 10 microseconds after changing the frequency of the second laser before selecting the second laser for output.

Example 5 includes the subject matter of any of Examples 1-4, and further including one or more photodetectors to detect light from the first laser and second laser scattered from an environment of the lidar system.

Example 6 includes the subject matter of any of Examples 1-5, and wherein the PIC die comprises the one or more photodetectors.

Example 7 includes the subject matter of any of Examples 1-6, and wherein the first laser is an extended cavity laser, the first laser comprising a first Bragg grating reflector; a first phase shifter to shift a frequency of the first laser between lines of the first Bragg grating reflector; and a second phase shifter to tune the frequency of the first laser within a line of the first Bragg grating reflector, wherein the second laser is an extended cavity laser, the second laser comprising a second Bragg grating reflector; a third phase shifter to shift a frequency of the second laser between lines of the second Bragg grating reflector; and a fourth phase shifter to tune the frequency of the second laser within a line of the second Bragg grating reflector; and a switch to select between the first laser and the second laser.

Example 8 includes the subject matter of any of Examples 1-7, and wherein the first phase shifter is a thermal phase shifter, wherein the third phase shifter is a thermal phase shifter, wherein the second phase shifter is a PN junction phase shifter, wherein the fourth phase shifter is a PN junction phase shifter.

Example 9 includes the subject matter of any of Examples 1-8, and wherein the first laser comprises an unbalanced Mach-Zehnder interferometer, wherein the first phase shifter is within one arm of the Mach-Zehnder interferometer of the first laser, wherein the second laser comprises an unbalanced Mach-Zehnder interferometer, wherein the third phase shifter is within one arm of the Mach-Zehnder interferometer of the second laser.

Example 10 includes the subject matter of any of Examples 1-9, and wherein the first laser further comprises a fifth phase shifter to tune a length of a cavity of the first laser, wherein the fifth phase shifter is a thermal phase shifter, wherein the second laser further comprises a sixth phase shifter to tune a length of a cavity of the second laser, wherein the sixth phase shifter is a thermal phase shifter.

Example 11 includes the subject matter of any of Examples 1-10, and wherein the switch comprises a balanced Mach-Zehnder interferometer with a PN junction phase shifter in one arm.

Example 12 includes the subject matter of any of Examples 1-11, and wherein the switch comprises a first amplifier connected to an output of the first laser, the first amplifier to amplify the output of the first laser when on and to attenuate the output of the first laser when off; and a second amplifier connected to an output of the second laser, the second amplifier to amplify the output of the second laser when on and to attenuate the output of the second laser when off.

Example 13 includes the subject matter of any of Examples 1-12, and wherein the first laser comprises a first amplifier separate from the first Bragg grating reflector, wherein the second laser comprises a second amplifier separate from the second Bragg grating reflector.

Example 14 includes the subject matter of any of Examples 1-13, and wherein the first laser comprises a first amplifier, wherein the first amplifier comprises the first Bragg grating reflector, wherein the second laser comprises a second amplifier, wherein the second amplifier comprises the second Bragg grating reflector.

Example 15 includes a photonic integrated circuit (PIC) die comprising a first laser comprising a first Bragg grating reflector; a first phase shifter optically coupled to the first Bragg grating reflector; and a second phase shifter optically coupled to the first Bragg grating reflector; a second laser comprising a second Bragg grating reflector; a third phase shifter optically coupled to the second Bragg grating reflector; and a fourth phase shifter optically coupled to the second Bragg grating reflector; and a switch to select between the first laser and the second laser.

Example 16 includes the subject matter of Example 15, and wherein the first laser is an extended cavity laser, wherein the second laser is an extended cavity laser.

Example 17 includes the subject matter of any of Examples 15 and 16, and wherein the first phase shifter is to shift a frequency of the first laser between lines of the first Bragg grating reflector, wherein the second phase shifter is to tune the frequency of the first laser within a line of the first Bragg grating reflector, wherein the third phase shifter is to shift a frequency of the second laser between lines of the second Bragg grating reflector, wherein the fourth phase shifter is to tune the frequency of the second laser within a line of the second Bragg grating reflector.

Example 18 includes the subject matter of any of Examples 15-17, and wherein the first phase shifter is a thermal phase shifter, wherein the third phase shifter is a thermal phase shifter, wherein the second phase shifter is a PN junction phase shifter, wherein the fourth phase shifter is a PN junction phase shifter.

Example 19 includes the subject matter of any of Examples 15-18, and wherein the first laser comprises an unbalanced Mach-Zehnder interferometer, wherein the first phase shifter is within one arm of the Mach-Zehnder interferometer of the first laser, wherein the second laser comprises an unbalanced Mach-Zehnder interferometer, wherein the third phase shifter is within one arm of the Mach-Zehnder interferometer of the second laser.

Example 20 includes the subject matter of any of Examples 15-19, and wherein the first laser further comprises a fifth phase shifter, wherein the fifth phase shifter is a thermal phase shifter, wherein the second laser further comprises a sixth phase shifter, wherein the sixth phase shifter is a thermal phase shifter.

Example 21 includes a lidar system comprising the PIC die of Example 15, wherein the lidar system is a frequency-modulated continuous-wave (FMCW) lidar system.

Example 22 includes a lidar system comprising the PIC die of Example 15, further comprising control circuitry to select the first laser for output; change a frequency of the second laser while the first laser is selected for output; select the second laser for output after the second laser has stabilized; and change a frequency of the first laser while the second laser is selected for output.

Example 23 includes the subject matter of Example 22, and wherein the switch comprises a balanced Mach-Zehnder interferometer with a PN junction phase shifter in one arm.

Example 24 includes the subject matter of any of Examples 22 and 23, and wherein the switch comprises a first amplifier connected to an output of the first laser, the first amplifier to amplify the output of the first laser when on and to attenuate the output of the first laser when off; and a second amplifier connected to an output of the second laser, the second amplifier to amplify the output of the second laser when on and to attenuate the output of the second laser when off.

Example 25 includes the subject matter of any of Examples 22-24, and wherein the first laser comprises a first amplifier separate from the first Bragg grating reflector, wherein the second laser comprises a second amplifier separate from the second Bragg grating reflector.

Example 26 includes the subject matter of any of Examples 22-25, and wherein the first laser comprises a first amplifier, wherein the first amplifier comprises the first Bragg grating reflector, wherein the second laser comprises a second amplifier, wherein the second amplifier comprises the second Bragg grating reflector.

Example 27 includes the subject matter of any of Examples 22-26, and further including one or more photodetectors to detect light from the laser means scattered from an environment of the lidar system.

Example 28 includes a lidar system comprising a photonic integrated circuit (PIC) die comprising laser means for a frequency-modulated continuous-wave (FMCW) lidar system; and control circuitry to control the laser means.

Example 29 includes the subject matter of Example 28, and wherein the control circuitry is to select a first laser of the laser means for output; change a frequency of a second laser of the laser means while the first laser is selected for output; select the second laser for output after the second laser has stabilized; and change a frequency of the first laser while the second laser is selected for output.

Example 30 includes the subject matter of any of Examples 28 and 29, and wherein to select the second laser for output comprises switching from the first laser to the second laser in less than 300 nanoseconds.

Example 31 includes the subject matter of any of Examples 28-30, and wherein the control circuitry is to allow the second laser to stabilize for at least 10 microseconds after changing the frequency of the second laser before selecting the second laser for output.

Example 32 includes the subject matter of any of Examples 28-31, and further including one or more photodetectors to detect light from the laser means scattered from an environment of the lidar system.

Example 33 includes the subject matter of any of Examples 28-32, and wherein the PIC die comprises the one or more photodetectors.

Example 34 includes the subject matter of any of Examples 28-33, and wherein the laser means comprises a first laser and a second laser, wherein the first laser is an extended cavity laser, the first laser comprising a first Bragg grating reflector; a first phase shifter to shift a frequency of the first laser between lines of the first Bragg grating reflector; and a second phase shifter to tune the frequency of the first laser within a line of the first Bragg grating reflector, wherein the second laser is an extended cavity laser, the second laser comprising a second Bragg grating reflector; a third phase shifter to shift a frequency of the second laser between lines of the second Bragg grating reflector; and a fourth phase shifter to tune the frequency of the second laser within a line of the second Bragg grating reflector; and a switch to select between the first laser and the second laser.

Example 35 includes the subject matter of any of Examples 28-34, and wherein the first phase shifter is a thermal phase shifter, wherein the third phase shifter is a thermal phase shifter, wherein the second phase shifter is a PN junction phase shifter, wherein the fourth phase shifter is a PN junction phase shifter.

Example 36 includes the subject matter of any of Examples 28-35, and wherein the first laser comprises an unbalanced Mach-Zehnder interferometer, wherein the first phase shifter is within one arm of the Mach-Zehnder interferometer of the first laser, wherein the second laser comprises an unbalanced Mach-Zehnder interferometer, wherein the third phase shifter is within one arm of the Mach-Zehnder interferometer of the second laser.

Example 37 includes the subject matter of any of Examples 28-36, and wherein the first laser further comprises a fifth phase shifter to tune a length of a cavity of the first laser, wherein the fifth phase shifter is a thermal phase shifter, wherein the second laser further comprises a sixth phase shifter to tune a length of a cavity of the second laser, wherein the sixth phase shifter is a thermal phase shifter.

Example 38 includes the subject matter of any of Examples 28-37, and wherein the switch comprises a balanced Mach-Zehnder interferometer with a PN junction phase shifter in one arm.

Example 39 includes the subject matter of any of Examples 28-38, and wherein the switch comprises a first amplifier connected to an output of the first laser, the first amplifier to amplify the output of the first laser when on and to attenuate the output of the first laser when off; and a second amplifier connected to an output of the second laser, the second amplifier to amplify the output of the second laser when on and to attenuate the output of the second laser when off.

Example 40 includes the subject matter of any of Examples 28-39, and wherein the first laser comprises a first amplifier separate from the first Bragg grating reflector, wherein the second laser comprises a second amplifier separate from the second Bragg grating reflector.

Example 41 includes the subject matter of any of Examples 28-40, and wherein the first laser comprises a first amplifier, wherein the first amplifier comprises the first Bragg grating reflector, wherein the second laser comprises a second amplifier, wherein the second amplifier comprises the second Bragg grating reflector.

1. A lidar system comprising:
a photonic integrated circuit (PIC) die comprising:
a first laser; and
a second laser; and
control circuitry to:
select the first laser for output;
change a frequency of the second laser while the first laser is selected for output;
select the second laser for output after the second laser has stabilized; and
change a frequency of the first laser while the second laser is selected for output.

2. The lidar system of claim 1, wherein the lidar system is a frequency-modulated continuous-wave (FMCW) lidar system.

3. The lidar system of claim 1, wherein to select the second laser for output comprises switching from the first laser to the second laser in less than 300 nanoseconds.

4. The lidar system of claim 1, wherein the control circuitry is to allow the second laser to stabilize for at least 10 microseconds after changing the frequency of the second laser before selecting the second laser for output.

5. The lidar system of claim 1, further comprising one or more photodetectors to detect light from the first laser and second laser scattered from an environment of the lidar system.

6. The lidar system of claim 1,
wherein the first laser is an extended cavity laser, the first laser comprising:
a first Bragg grating reflector;
a first phase shifter to shift a frequency of the first laser between lines of the first Bragg grating reflector; and
a second phase shifter to tune the frequency of the first laser within a line of the first Bragg grating reflector,
wherein the second laser is an extended cavity laser, the second laser comprising:
a second Bragg grating reflector;
a third phase shifter to shift a frequency of the second laser between lines of the second Bragg grating reflector; and
a fourth phase shifter to tune the frequency of the second laser within a line of the second Bragg grating reflector; and
a switch to select between the first laser and the second laser.

7. A photonic integrated circuit (PIC) die comprising:
a first laser comprising:
a first Bragg grating reflector;
a first phase shifter optically coupled to the first Bragg grating reflector; and
a second phase shifter optically coupled to the first Bragg grating reflector;
a second laser comprising:
a second Bragg grating reflector;
a third phase shifter optically coupled to the second Bragg grating reflector; and
a fourth phase shifter optically coupled to the second Bragg grating reflector; and
a switch to select between the first laser and the second laser.

8. The PIC die of claim 7, wherein the first phase shifter is a thermal phase shifter, wherein the third phase shifter is a thermal phase shifter, wherein the second phase shifter is a PN junction phase shifter, wherein the fourth phase shifter is a PN junction phase shifter.

9. The PIC die of claim 8, wherein the first laser comprises an unbalanced Mach-Zehnder interferometer, wherein the first phase shifter is within one arm of the Mach-Zehnder interferometer of the first laser, wherein the second laser comprises an unbalanced Mach-Zehnder interferometer, wherein the third phase shifter is within one arm of the Mach-Zehnder interferometer of the second laser.

10. The PIC die of claim 8, wherein the first laser further comprises a fifth phase shifter, wherein the fifth phase shifter is a thermal phase shifter, wherein the second laser further comprises a sixth phase shifter, wherein the sixth phase shifter is a thermal phase shifter.

11. The PIC die of claim 7, wherein the switch comprises a balanced Mach-Zehnder interferometer with a PN junction phase shifter in one arm.

12. The PIC die of claim 7, wherein the switch comprises:
a first amplifier connected to an output of the first laser, the first amplifier to amplify the output of the first laser when on and to attenuate the output of the first laser when off; and
a second amplifier connected to an output of the second laser, the second amplifier to amplify the output of the second laser when on and to attenuate the output of the second laser when off.

13. The PIC die of claim 7, wherein the first laser comprises a first amplifier separate from the first Bragg grating reflector, wherein the second laser comprises a second amplifier separate from the second Bragg grating reflector.

14. The PIC die of claim 7, wherein the first laser comprises a first amplifier, wherein the first amplifier comprises the first Bragg grating reflector, wherein the second laser comprises a second amplifier, wherein the second amplifier comprises the second Bragg grating reflector.

15. The PIC die of claim 7, further comprising one or more photodetectors.

16. The PIC die of claim 7, wherein the first laser is an extended cavity laser, wherein the second laser is an extended cavity laser.

17. The PIC die of claim 7, wherein the first phase shifter is to shift a frequency of the first laser between lines of the first Bragg grating reflector,
wherein the second phase shifter is to tune the frequency of the first laser within a line of the first Bragg grating reflector,
wherein the third phase shifter is to shift a frequency of the second laser between lines of the second Bragg grating reflector,
wherein the fourth phase shifter is to tune the frequency of the second laser within a line of the second Bragg grating reflector.

18. A lidar system comprising:
a photonic integrated circuit (PIC) die comprising laser means for a frequency-modulated continuous-wave (FMCW) lidar system; and
control circuitry to control the laser means.

19. The lidar system of claim 18, wherein the control circuitry is to:
select a first laser of the laser means for output;
change a frequency of a second laser of the laser means while the first laser is selected for output;
select the second laser for output after the second laser has stabilized; and
change a frequency of the first laser while the second laser is selected for output.

20. The lidar system of claim 18,
wherein the laser means comprises a first laser and a second laser,
wherein the first laser is an extended cavity laser, the first laser comprising:
a first Bragg grating reflector;
a first phase shifter to shift a frequency of the first laser between lines of the first Bragg grating reflector; and
a second phase shifter to tune the frequency of the first laser within a line of the first Bragg grating reflector,
wherein the second laser is an extended cavity laser, the second laser comprising:
a second Bragg grating reflector;
a third phase shifter to shift a frequency of the second laser between lines of the second Bragg grating reflector; and
a fourth phase shifter to tune the frequency of the second laser within a line of the second Bragg grating reflector; and
a switch to select between the first laser and the second laser.
